(19) United States
(12) Patent Application Publication
(10) Pub. No.: US 2025/0287605 A1
(43) Pub. Date: Sep. 11, 2025

(54) SEMICONDUCTOR DEVICE WITH LOW CURRENT LEAKAGE AND METHOD FOR MANUFACTURING THE SAME

(71) Applicant: TAIWAN SEMICONDUCTOR MANUFACTURING COMPANY, LTD., Hsinchu (TW)

(72) Inventors: Yen-Chieh HUANG, Hsinchu (TW); Huai-Ying HUANG, Hsinchu (TW); Yu-Chuan SHIH, Hsinchu (TW); Chun-Chieh LU, Hsinchu (TW); I-Che LEE, Hsinchu (TW); Yu-Ming LIN, Hsinchu (TW)

(73) Assignee: TAIWAN SEMICONDUCTOR MANUFACTURING COMPANY, LTD., Hsinchu (TW)

(21) Appl. No.: 18/600,934

(22) Filed: Mar. 11, 2024

(51) Int. Cl. H10B 51/30; H01L 21/28; H01L 29/417; H01L 29/51; H01L 29/66; H01L 29/78; H01L 29/786

(52) U.S. Cl. CPC H10B 51/30; H10D 30/031; H10D 30/0415; H10D 30/6729; H10D 30/6755; H10D 30/6757; H10D 30/701; H10D 64/033; H10D 64/689

(57) ABSTRACT

A method for manufacturing a semiconductor structure includes: forming a gate electrode; forming a gate dielectric layer over the gate electrode; forming a channel over the gate dielectric layer opposite to the gate electrode, the channel including a semiconductor material; forming a first confinement layer on the channel opposite to the gate electrode, an energy band gap of the first confinement layer being greater than an energy band gap of the channel; and forming a drain electrode and a source electrode which are connected to the channel, the drain electrode and the source electrode being spaced apart from each other and each including an electrically conductive material.

### BACKGROUND

Thin film transistors, which are manufactured using thin film techniques, are known to be used in various applications. The thin film transistors may be formed in a front-end-of-line process, or may be embedded in a back-end-of-line interconnect structure, thereby reducing chip area of an integrated circuit. The thin-film transistors with low current leakage are under continuous development.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating a semiconductor structure including a semiconductor device in accordance with some embodiments.

FIGS. 2 and 3 are each a schematic sectional view illustrating the semiconductor device in accordance with some other embodiments.

FIG. 4 is a flow diagram illustrating a method for manufacturing the semiconductor device in accordance with some embodiments.

FIGS. 5 to 11 illustrate schematic views of intermediate stages of the method depicted in FIG. 4 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

In some applications, a gate dielectric layer of a thin-film transistor (TFT) may be made of a ferroelectric material, and such thin-film transistor (also referred to as a field-effect transistor (FeFET)) may function as a memory device capable of storing binary data. In the case that the FeFET includes an n-channel (i.e., a channel having an n-type conductivity), the threshold voltage of the FeFET (in an initial state, a programmed state and/or an erased state) may be a negative value, indicating that a current (i.e., current leakage) is present in the n-channel when no voltage is applied. Therefore, in order to reduce the current leakage, the present disclosure provides a semiconductor device having a relatively positive threshold voltage when an n-channel is included therein, or a semiconductor device having a relatively negative threshold voltage when a p-channel (i.e., a channel having a p-type conductivity) is included therein.

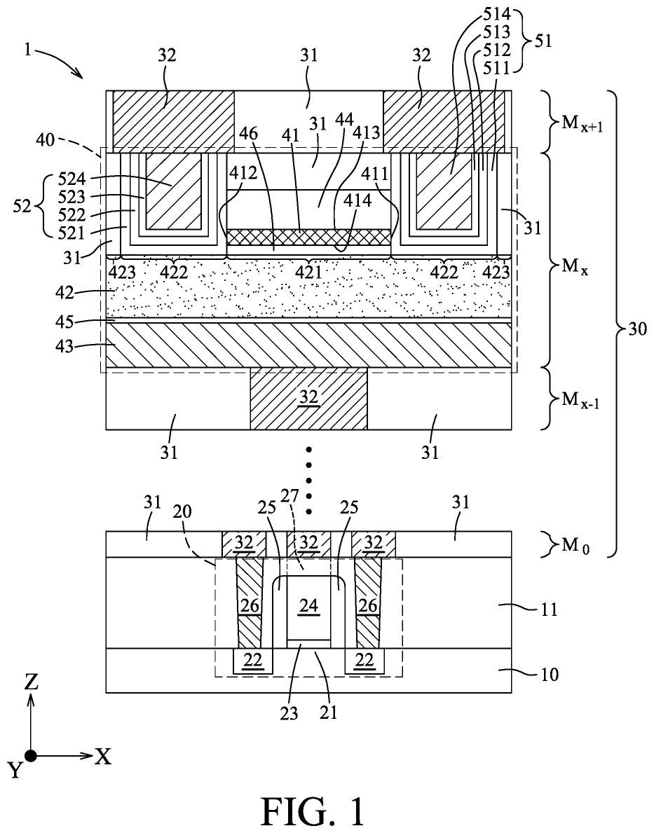

FIG. 1 is a schematic sectional view illustrating a semiconductor structure 1 in accordance with some embodiments. The semiconductor structure 1 includes a substrate 10, a first semiconductor device 20 (which serves as a front-end-of-line (FEOL) transistor), an inter-layer dielectric (ILD) layer 11 formed on the substrate 10 to cover the first semiconductor device 10, an interconnect structure 30 formed on the ILD layer 11, and a second semiconductor device 40 (which serves as a back-end-of-line (BEOL) transistor) formed in the interconnect structure 30. It is noted that the second semiconductor device 40 is not limited to be located directly above the first semiconductor device 20. In some other embodiments, the first semiconductor device 20 shown in FIG. 1 may be omitted. In such case, the second semiconductor device 40 may be directly formed on the substrate 10, or formed on a buffer layer (not shown) that is preformed on the substrate 10 and that is used for improving the film quality of a film to be formed thereon.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 10 may be configured as a semiconductor-on-insulator substrate. In some embodiments, the semiconductor material in the substrate 10 may be un-doped, or may be doped with impurities (e.g., n-type impurities or p-type impurities) to form a well portion for the first semiconductor device 20. In some yet other embodiments, the substrate 10 may be a glass substrate. Other suitable materials and configurations for the substrate 10 are within the contemplated scope of the present disclosure.

In some embodiments, the first semiconductor device 20 may be a field-effect transistor (FET), and includes a channel 21, two source/drain portions 22 formed at two opposite sides of the channel 21, a gate dielectric layer 23 formed on the channel 21, a gate electrode 24 formed on the gate dielectric layer 23 such that the channel 21 is spaced apart from the gate electrode 24 by the gate dielectric layer 23, and two dielectric spacers 25 formed at two opposite sides of the gate electrode 24. In some embodiments, the first semiconductor device 20 further includes two source/drain contacts 26 and a gate contact 27 formed in the ILD layer 11 and spaced apart from each other. The source/drain contacts 26 are respectively formed on the source/drain portions 22, and the gate contact 27 is formed on the gate electrode 24. In some embodiments, as shown in FIG. 1, the first semiconductor device 20 may be configured as a planar FET, in which (i) the source/drain portions 22 are formed in the substrate 10 by an implantation process, and (ii) a portion of the substrate 10, which is located between the source/drain portions 22, serves as the channel 21. The source/drain portions 22 may be doped with impurities to have an n-type conductivity or a p-type conductivity according to the type of the first semiconductor device 20 (i.e., the source/drain portions 22 have the n-type conductivity when the first semiconductor device 20 is an n-FET; and the source/drain portions 22 have the p-type conductivity when the first semiconductor device 20 is a p-FET). In some embodiments, the gate dielectric layer 23 may be made of silicon oxide, and the gate electrode 24 may be made of polycrystalline silicon. In some other embodiments not shown herein, the first semiconductor device 20 may be configured as a fin-type field-effect transistor (FinFET), or a gate-all-around field-effect transistor (GAAFET). In such case, the gate dielectric layer 23 may include a high dielectric constant (high-k) material, and the gate electrode 24 include a metallic material. Other three-dimensional (3D) transistor structures suitable for the first semiconductor device 20 are within the contemplated scope of the present disclosure.

In some embodiments, the ILD layer 11 includes a dielectric material. In some embodiments, the dielectric material for forming the ILD layer 11 may have a low dielectric constant, and may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), or combinations thereof. Other dielectric materials suitable for the ILD layer 11 are within the contemplated scope of the present disclosure. The interconnect structure 30 includes a plurality of interconnect layers which are sequentially formed on the ILD layer 11. Four of the interconnect layers are exemplarily shown in FIG. 1, and are respectively represented by M₀, Mₓ₋₁, Mₓ, Mₓ₊₁, where x is an integer not less than 2. Other interconnect layers between the interconnect layers M₀ and Mₓ₋₁ are omitted. Each of the interconnect layers M₀, . . . . Mₓ₋₁, Mₓ, Mₓ₊₁ includes an inter-metal dielectric (IMD) portion 31, and a plurality of electrically conductive elements 32 (for example, metal contacts, metal lines, and/or metal vias) formed in the IMD portion 31. Each of the electrically conductive elements 32 in each of the interconnect layers M₀, . . . . Mₓ₋₁, Mₓ, Mₓ₊₁ is connected to a corresponding one of the electrically conductive elements 32 in an adjacent one of the interconnect layers M₀, . . . . Mₓ₋₁, Mₓ, Mₓ₊₁. In some embodiments, the second semiconductor device 40 is formed in the IMD portion 31 of the interconnect layer Mₓ. In some embodiments, the electrically conductive elements 32 may include a low resistance electrically conductive material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), golden (Au), silver (Ag), aluminum (Al), osmium (Os), alloys thereof, or combinations thereof. Possible low dielectric constant (low-k) materials suitable for the IMD portion 31 are similar to those for forming the ILD layer 11, and thus the details thereof are omitted for the sake of brevity.

In some embodiments, the second semiconductor device 40 may be a thin-film transistor (TFT), and includes a channel 41 that includes a semiconductor material, a gate dielectric layer 42 formed on the channel 41, a gate electrode 43 formed on the gate dielectric layer 42 such that the channel 41 is separated from the gate electrode 43 by the gate dielectric layer 42, a drain contact unit 51 and a source contact unit 52 connected to the channel 41 and spaced apart from each other, and a first confinement layer 44 disposed on the channel 41 opposite to the gate electrode 43.

In some embodiments, as shown in FIG. 1, the gate electrode 43 is located beneath the channel 41 such that the gate electrode 43 and the channel 41 are respectively located proximate to and distal from the substrate 10. In such case, the second semiconductor device 40 is referred to as a bottom-gate TFT, but is not limited thereto. In some other embodiments not shown herein, the second semiconductor device 40 may be configured as a top-gate TFT, a double-gate TFT, a vertical TFT, or 3-dimensional TFT. For the top-gate TFT, the gate electrode and the channel are respectively located distal from and proximate to the substrate. The double gate TFT includes a lower gate electrode and an upper gate electrode which are respectively separated from the channel by a lower gate electric layer and an upper gate dielectric layer. The lower and upper gate electrodes are disposed at two opposite sides of the channel, and are respectively located proximate to and distal from the substrate. In some embodiments, the second semiconductor device 40 may be applied to static random-access memory (SRAM), dynamic random-access memory (DRAM, e.g., one-transistor/one-capacitor (1T-1C) DRAM cell, 3-dimensional DRAM structure, standalone DRAM structure, embedded DRAM structure, etc.), ferroelectric memories (e.g., 1T-1C ferroelectric random-access memory memory (1T-1C FeRAM), 1T FeRAM, metal-ferroelectric-metal field-effect transistor-based (MFMFET-based) FeRAM, metal-ferroelectric-metal-insulator-semiconductor field-effect transistor-based (MFMISFET) FeRAM, etc.), or peripheral devices (e.g., power gates, input/output (I/O) devices, or selectors for memory cells, etc.). It is noted that the second semiconductor device 40 is not limited to be formed in the IMD portion 31 of the interconnect layer Mₓ. In some embodiments not shown herein, the second semiconductor device 40 may be formed in any one of the interconnect layers M₀, . . . . Mₓ₋₁, Mₓ₊₁.

In some embodiments, as shown in FIG. 1, the gate electrode 43 is formed on the IMD portion 31 of the interconnect layer Mₓ₋₁, and is connected to one of the electrically conductive elements 32 of the interconnect layer Mₓ₋₁. In some embodiments, the gate electrode 43 includes tungsten (W), platinum (Pt), aluminum (Al), silver (Ag), copper (Cu), nickel (Ni), or alloys thereof. Other metallic material suitable for forming the gate electrode 43 are within the contemplated scope of the present disclosure.

In some embodiments, the gate dielectric layer 42 is formed on the gate electrode 43 (in other words, the gate electrode 43 is formed on a lower surface of the gate dielectric layer 42). In some embodiments, the gate dielectric layer 42 may include silicon oxide, silicon nitride, silicon oxynitride, or a high-k dielectric material (such as hafnium oxide, hafnium tantalum oxide, zirconium oxide, zirconium aluminum oxide, hafnium aluminum oxide, hafnium silicon oxide, aluminum oxide, etc.). In some other embodiments, when the second semiconductor device 40 is formed as a FeRAM, the gate dielectric layer 42 may include a ferroelectric material (such as hafnium zirconium oxide (HZO), barium titanate (BaTiO₃), lead titanate, lead zirconate, lithium niobate, sodium niobate, potassium niobate, potassium tantalite, bismuth scandate, bismuth ferrite, aluminum scandium nitride, or hafnium oxide doped with yttrium (Y), lanthanum (La), gadolinium (Gd), erbium (Er), titanium (Ti), zirconium (Zr), aluminum (Al), or tantalum (Ta)). Other suitable materials for the gate dielectric layer 42 are within the contemplated scope of disclosure. In some embodiments, the gate dielectric layer 42 has a thickness ranging from about 1 nm to about 500 nm. In some embodiments, as shown in FIG. 1, the gate dielectric layer 42 has a first region 421 for forming the channel 41 thereon, two second regions 422 respectively for forming the drain contact unit 51 and the source contact unit 52 thereon, and a third region 423 for being covered by the IMD portion 31 of the interconnect layer Mₓ. The regions 421, 422, 423 are displaced from each other.

In some embodiments, the channel 41 is formed on the first portion 421 of the gate dielectric layer 42 (in other words, the gate dielectric layer 42 is formed on a lower surface of the channel 41). In some embodiments, the semiconductor material for forming the channel 41 includes silicon (Si), germanium (Ge), silicon germanium, silicon germanium carbide, gallium arsenic, indium phosphide, gallium phosphide, gallium nitride, gallium antimony, aluminum arsenic, indium arsenic, indium antimony, aluminum gallium arsenic, gallium indium arsenic, gallium indium phosphide, indium aluminum arsenic, aluminum indium gallium phosphide, cadmium sulfide, cadmium selenide, zinc sulfide, zinc selenide, zinc telluride, lead sulfide, lead telluride, mercury telluride, or combinations thereof. In some other embodiments, the semiconductor material for forming the channel 41 may have an n-type conductivity. That is, the channel 41 may include an n-type metal oxide semiconductor, such as indium gallium zinc oxide (IGZO), indium zinc oxide (IZO), indium gallium tin oxide (IGSnO), indium gallium tin zinc oxide (IGSnZnO), which has extra charge carriers (i.e., electrons) capable of moving in the channel 41 during operation of the second semiconductor device 40. In such case, the second semiconductor device 40 using the n-type metal oxide semiconductor as the channel 41 is referred to as an n-type TFT, electrons are majority carriers in the channel 41, and such channel 41 may be referred to as an n-channel. In some embodiments, when the channel 41 is made of IGZO, such IGZO may be represented by a chemical formula of (Ga₂)ₓ₁(In₂)₍₁₋ₓ₁₎Zn_{y1}O₇, where x1 ranges from about 0.2 to about 0.75, and y1 is greater than zero and not greater than about 0.75. In some yet other embodiments, the semiconductor material for forming the channel 41 may have a p-type conductivity. That is, the channel 41 may include a p-type metal oxide semiconductor, such as copper oxide (Cu₂O), tin oxide (SnO), nickel oxide (NiO), K₂Sn₂O₃, Al-doped NiO (Al:NiO), V-doped NiO (V:NiO), Cu-doped NiO (Cu:NiO), Sn-doped NiO (Sn:NiO), Mg-doped NiO (Mg:NiO), Li-doped MgNiO (Li:MgNiO), RbSn₂O₃, TiSnO₃, Sn₅(PO₅)₂, Ta₂Sn₂O₆, Pb-doped CsSnI₃ (Pb:CsSnI₃), CuCrO₂, Mg-doped Cu₂O (Mg:Cu₂O), CuFeO₂, CsPbIBr₂, or phenyl-C61-butyric acid methyl ester (PCBM), which has extra charge carriers (i.e., holes) capable of moving in the channel 41 during operation of the second semiconductor device 40. In such case, the second semiconductor device 40 using the p-type metal oxide semiconductor as the channel 41 is referred to as a p-type TFT, holes are majority carriers in the channel 41, and such channel 41 may be referred to as a p-channel. In some embodiments, the channel 41 may have a thickness ranging from about 1 nm to about 100 nm.

In some embodiments, the drain contact unit 51 and the source contact unit 52 are respectively disposed on the second regions 422 of the gate dielectric layer 42, and are respectively located at two opposite sides of the channel 41 (in other words, the drain contact unit 51 and the source contact unit 52 are respectively connected to a drain-side surface 411 and a source-side surface 412 of the channel 41). In some embodiments in which the second semiconductor device 40 is formed as a TFT, when a specified voltage (V_{GS}) is applied between the gate electrode 43 and the source contact unit 52 to bias the second semiconductor device 40 to an on-state, the majority carriers (electrons in an n-channel or holes in a p-channel) may flow in a direction from the source contact unit 52 toward the drain contact unit 51, and thus an on-state drain current (Iₒₙ) may be detected at the drain contact unit 51. In some embodiments, the on-state drain current (Iₒₙ) may increase as the thickness of the channel 41 increases. For example, the on-state drain current (Iₒₙ) may increase from about 60 μA/μm to about 200 μA/μm as the thickness of the channel 41 increases from about 1 nm to about 100 nm. In some other embodiments, when the second semiconductor device 40 serves as a memory device (e.g., a FeRAM), and includes the drain and source contact units 51, 52 having the arrangement as described above (i.e., the drain and source contact units 51, 52 are in direct contact with the gate dielectric layer 42), a polarizable region of the gate dielectric layer 42 can be enlarged, and a memory window of the FeRAM may be enlarged accordingly. Furthermore, when a read voltage (V_{GS}) is applied between the gate electrode 43 and the source contact unit 52, the majority carriers (electrons in an n-channel or holes in a p-channel) may flow in a direction from the source contact unit 52 toward the drain contact unit 51, and thus a programmed state or an erased state of the FeRAM may be determined according to the on-state drain current (Iₒₙ) detected at the drain contact unit 51.

In some embodiments, as shown in FIG. 1, the drain contact unit 51 includes a drain-side barrier layer 511 connected to the drain-side surface 411 of the channel 41, a drain-side conductive metal oxide layer 512 formed on the drain-side barrier layer 511, a drain-side diffusion blocking layer 513 formed on the drain-side conductive metal oxide layer 512, and a drain electrode 514 formed on the drain-side diffusion blocking layer 513. The source contact unit 52 includes a source-side barrier layer 521 connected to the second-side surface 412 of the channel 41, a source-side conductive metal oxide layer 522 formed on the source-side barrier layer 521, a source-side diffusion blocking layer 523 formed on the source-side conductive metal oxide layer 522, and a source electrode 524 formed on the source-side diffusion blocking layer 523.

The drain-side barrier layer 511 is provided to form a first barrier height at a first interface between the drain-side barrier layer 511 and the channel 41, and the source-side barrier layer 521 is provided to form a second barrier height at a second interface between the source-side barrier layer 521 and the channel 41. The first barrier height and the second barrier height may vary depending on the types of materials selected for the drain-side barrier layer 511 and the source-side barrier layer 521, and thus a threshold voltage of the second semiconductor device 40 may be varied. In some embodiments in which the semiconductor device 40 serves as a memory device, the threshold voltage of the semiconductor device 40 may be an initial threshold voltage (i.e., the threshold voltage when the memory device 40 is in an initial state, Vₜ₍ᵢₙᵢₜᵢₐₗ₎), a programmed threshold voltage (i.e., the threshold voltage when the memory device 40 is in a programmed state, V_{t(PRG)}), or an erased threshold voltage (i.e., the threshold voltage when the memory device 40 is in an erased state, V_{t(ERS)}). In some embodiments, an energy band gap of the drain-side barrier layer 511 is greater than an energy band gap of the channel 41. In some embodiments, an energy band gap of the source-side barrier layer 521 is greater than the energy band gap of the channel 41.

In some embodiments in which the second semiconductor device 40 is an n-type TFT and the channel 41 is an n-channel (i.e., the semiconductor material for forming the channel 41 has an n-type conductivity), with the provision of the drain-side and source-side barrier layers 511, 521 (each having a conduction band edge energy that is higher than a conduction band edge energy of the n-channel 41), the threshold voltage of the n-type TFT 40 can be shifted from a relatively negative value (without the drain-side and source-side barrier layers 511, 521) to a relatively positive value (a negative value with a smaller absolute value or a positive value). As such, when no voltage is applied to the semiconductor device 40 or the semiconductor device 40 is in a standby mode, a static power dissipation, which results from leakage current in the semiconductor device 40, may be suppressed. The first barrier height formed at the first interface is the difference between the conduction band edge energy of the n-channel 41 and the conduction band edge energy of the drain-side barrier layer 511, and may be referred to as a first electron barrier height. The second barrier height formed at the second interface is the difference between the conduction band edge energy of the n-channel 41 and the conduction band edge energy of the source-side barrier layer 521, and may be referred to as a second electron barrier height. In some embodiments, the first electron barrier height is greater than the second electron barrier height, and thus degradation of an on-state drain current may be prevented or alleviated (i.e., the on-state drain current (Iₒₙ) of the second semiconductor device 40 is relatively large).

In some embodiments in which the second semiconductor device 40 is an n-type TFT, the drain-side barrier layer 511 includes a drain barrier material, and the source-side barrier layer 521 includes a source barrier material. Each of the drain barrier material and source barrier material may be independently selected from gallium oxide, silicon oxide, or aluminum oxide. In some embodiments, each of the drain-side barrier layer 511 and the source-side barrier layer 521 may further include dopants so as to adjust the energy band gap of the drain-side barrier layer 511 (or the source-side barrier layer 521). In some embodiments, first dopants doped in the drain barrier material include indium, zinc or a combination thereof. In some embodiments, second dopants doped in the source barrier material include indium, zinc or a combination thereof. For example, each of the drain-side barrier layer 511 and the source-side barrier layer 521, which may be made of gallium oxide, zinc-doped gallium oxide or indium-doped gallium oxide, may be represented by a chemical formula of (Gaₓ₁A₍₁₋ₓ₁₎)O_{y1}, where A is Zn or In, x1 ranges from about 0.1 to about 1, and y1 ranges from about 0.1 to about 3. As a concentration of the first dopants in the drain-side barrier layer 511 (or a concentration of the second dopants in the source-side barrier layer 521) increases, the energy band gap of the drain-side barrier layer 511 (or the source-side barrier layer 521) decreases. The greater the energy band gap of each of the drain-side and source-side barrier layers 511, 521 is, the greater the shift of the threshold voltage of the n-type TFT 40 is. In other words, with the provision of the drain-side and source-side barrier layers 511, 521 each having a relatively great energy band gap, the n-type TFT 40 may have a relatively positive threshold voltage, and thus the static power dissipation (leakage current) may be suppressed.

In some other embodiments in which the second semiconductor device 40 is a p-type TFT and the channel 41 is a p-channel, with the provision of the drain-side and source-side barrier layers 511, 521 (each having a valence band edge energy that is lower than a valence band edge energy of the p-channel 41), the threshold voltage of the p-type TFT 40 can be shifted from a relatively large positive value (without the drain-side and source-side barrier layers 511, 521) toward a relative small positive value or a negative value, thereby suppressing the static power dissipation of the second semiconductor device 40. The first barrier height formed at the first interface is the difference between the valence band edge of the p-channel 41 and the valence band edge energy of the drain-side barrier layer 511, and may be referred to as a first hole barrier height. The second barrier height formed at the second interface is the difference between the valence band edge energy of the p-channel 41 and the valence band edge energy of the source-side barrier layer 521, and may be referred to as a second hole barrier height. In some embodiments, the first hole barrier height is greater than the second hole barrier height, and thus degradation of an on-state drain current may be prevented or alleviated (i.e., the on-state drain current (Iₒₙ) of the second semiconductor device 40 is relatively large).

In some embodiments in which the second semiconductor device 40 is a p-type TFT, each of the drain-side and source-side barrier layers 511, 521 may be independently selected from TiSnO₃, Sn₅(PO₅)₂, Ta₂SnO₆, Cs-doped nickel oxide (Cs:NiOₓ), or bathocuproine. In other words, each of the drain barrier material and the source barrier material may be independently selected from TiSnO₃, Sn₅(PO₅)₂, Ta₂SnO₆, nickel oxide (NiOₓ), or bathocuproine, and each of the first dopants and the second dopants may be independently selected from cesium (Cs), or other suitable dopants.

In some embodiments, each of the drain barrier material and the source barrier material may have a crystalline phase, an amorphous phase or a combination thereof. In some embodiments, the drain-side barrier layer 511 has a first thickness ranging from about 1 Å to about 300 Å. In some embodiments, the source-side barrier layer 521 has a second thickness ranging from about 1 Å to about 300 Å. The greater the thickness of each of the drain-side and source side barrier layers 511, 521 (or the higher percentage of crystalline phase in each of the drain-side and source side barrier layers 511, 521) is, the greater the shift of the threshold voltage of the n-type TFT 40 (or the p-type TFT 40) is.

In order to prevent or alleviate degradation of an on-state drain current, the energy band gap of the drain-side barrier layer 511 is higher than the energy band gap of the source-side barrier layer 521. In some embodiments, when the same dopants are applied to the drain-side and source-side barrier layers 511, 521, a dopant concentration in the drain-side barrier layer 511 is less than a dopant concentration in the source-side barrier layer 521 and/or the second thickness is less than the first thickness.

In some embodiments, the drain-side conductive metal oxide layer 512 (or the source-side conductive metal oxide layer 522) is used to reduce a contact resistance between the channel 41 and the drain electrode 514 (or the source electrode 524). As such, each of the drain-side and source-side conductive metal oxide layers 512, 522 has an electrically conductivity which is lower than that of each of the drain and source electrodes 514, 524, and which is higher than that of the channel 41. In addition, the electrically conductivity of each of the drain-side and source-side conductive metal oxide layers 512, 522 is higher than that of each of the drain-side and source-side barrier layers 511, 521. In some embodiments, the drain-side conductive metal oxide layer 512 is in ohmic contact with the drain-side barrier layer 511 and the drain-side diffusion blocking layer 513. In some embodiments, the source-side conductive metal oxide layer 522 is in ohmic contact with the source-side barrier layer 521 and the source-side diffusion blocking layer 523. In some embodiments, each of the drain-side and source-side conductive metal oxide layers 512, 522 may be independently made of indium gallium zinc oxide (IGZO), indium gallium oxide (IGO), indium zinc oxide (IZO), indium oxide, zinc oxide, zinc tin oxide (ZnSnO, ZTO), gallium zinc oxide (GZO), indium tin oxide (InSnO, ITO), fluorine-doped tin oxide (FTO), or other high conductive metal oxides having high donor (i.e., electrons) density. It is noted that, in comparison with the n-type metal oxide semiconductor for forming the channel 41 (such as the examples described in the previous paragraph), the metal oxides for forming the drain-side and source-side conductive metal oxide layers 512, 522 has a relatively high donor (i.e., electrons) density. In other words, the conductivity of the metal oxides for forming the drain-side and source-side conductive metal oxide layers 512, 522 is greater than the conductivity of the metal oxide semiconductor for forming the channel 41. In some embodiments, each of the drain-side and source-side conductive metal oxide layers 512, 522 may have a thickness ranging from about 5 nm to about 500 nm. The thicknesses of the drain-side and source-side conductive metal oxide layers 512, 522 may be the same as or different from each other.

In some embodiments, each of the drain-side and source-side diffusion blocking layers 513, 523 is provided for preventing metal atoms in a corresponding one of the drain and source electrodes 514, 524 from diffusing into the IMD portion 31 of the interconnect layer Mₓ, so that undesired current leakage may be eliminated. In some embodiments, each of the drain-side and source-side diffusion blocking layers 513, 523 may include titanium nitride (TiN), tungsten carbon nitride (WCN), tungsten nitride (WN), tantalum nitride (TaN), etc. Other materials suitable for forming the drain-side and source-side diffusion blocking layers 513, 523 are also within the contemplated scope of the present disclosure. In some embodiments, each of the drain-side and source-side diffusion blocking layers 513, 523 may have a thickness ranging from about 0.5 Å to about 50 nm.

In some embodiments, the drain electrode 514 includes a first electrically conductive material, and the source electrode 524 includes a second electrically conductive material. The first electrically conductive material may be the same as or different from the second electrically conductive material. Each of the first and second electrically conductive materials may include tungsten (W), platinum (Pt), aluminum (Al), cobalt (Co), copper (Cu), titanium (Ti), tantalum (Ta), zirconium (Zr), hafnium (Hf), or alloys thereof. Other metallic materials suitable for forming the drain and source electrodes 514, 524 are within the contemplated scope of the present disclosure.

In some embodiments, each of the drain and source electrodes 514, 524 has an upper surface distal from the substrate 10, a lower surface proximate to the surface 10, and an interconnecting surface connecting the upper surface and the lower surface. In some embodiments, a drain-side film stack includes the drain-side barrier layer 511, the drain-side conductive metal oxide layer 512 and the drain-side diffusion blocking layer 513 stacked on each other in such order, and a source-side film stack includes the source-side barrier layer 521, the source-side conductive metal oxide layer 522 and the source-side diffusion blocking layer 523 stacked on each other in such order. In some embodiments, as shown in FIG. 1, the drain-side film stack and the source-side film stack are respectively formed around the drain electrode 514 and the source electrode 524 such that the lower surface and the interconnecting surface of each of the drain and source electrodes 514, 524 are covered by a respective one of the drain-side and source-side film stacks. In such case, not only the channel 41 is separated from each of the drain and source electrodes 514, 524 by a respective one of the drain-side and source-side film stacks, but also the gate dielectric layer 42 is separated from each of the drain and source electrodes 514, 524 by a respective one of the drain-side and source-side film stacks.

In some embodiments, as shown in FIG. 1, the first confinement layer 44 is formed on a back surface 413 of the channel 41 opposite to a front surface 414 of the channel 41. Each of the back surface 413 and the front surface 414 interconnects the drain-side surface 411 and the source-side surface 412. The back surface 413 and the front surface 414 are respectively located distal from and proximate to the gate electrode 43. An energy band gap of the first confinement layer 44 is greater than the energy band gap of the channel 41. In some embodiments in which the second semiconductor device 40 is an n-type TFT and the channel 41 is an n-channel, a conduction band edge energy of the first confinement layer 44 is higher than the conduction band edge energy of the channel 41. In some other embodiments in which the second semiconductor device 40 is a p-type TFT and the channel 41 is a p-channel, a valence band edge energy of the first confinement layer 44 is lower than the valence band edge energy of the channel 41. Since a first carrier barrier height (i.e., the difference in the conduction band edge energy or the difference in the valence band edge energy) is formed at a first heterojunction between the channel 41 and the first confinement layer 44, the majority carriers (electrons in an n-channel or holes in a p-channel) are confined to flow within the channel 41 by the first confinement layer 44, thereby reducing a back-channel leakage current.

In some embodiments in which the second semiconductor device 40 is an n-type TFT, the first confinement layer 44 includes a first base material selected from gallium oxide, silicon oxide, or aluminum oxide. In some embodiments, the first confinement layer 44 has a first thickness ranging from about 1 Å to about 300 Å. In some embodiments, the first confinement layer 44 may further include first doping elements so as to adjust the energy band gap of the first confinement layer 44. In some embodiments, the first doping elements doped in the first base material include indium, zinc or a combination thereof. For example, the first confinement layer 44, which may be made of gallium oxide, zinc-doped gallium oxide or indium-doped gallium oxide, may be represented by a chemical formula of (Gaₓ₂Q₍₁₋ₓ₂₎)O_{y2}, where Q is Zn or In, x2 ranges from about 0.1 to about 1, and y2 ranges from about 0.1 to about 3. As a concentration of the first doping elements in the first confinement layer 44 increases, the energy band gap of the first confinement layer 44 decreases. The greater the energy band gap (or the greater thickness) of the first confinement layer 44 is, the more effective the reduction of the back-channel leakage current is. In some other embodiments in which the second semiconductor device 40 is a p-type TFT, the first confinement layer 44 may be selected from TiSnO₃, Sn₅(PO₅)₂, Ta₂SnO₆, Cs-doped nickel oxide (Cs:NiOₓ), or bathocuproine. In other words, the first base material may be selected from TiSnO₃, Sn₅(PO₅)₂, Ta₂SnO₆, nickel oxide (NiOₓ), or bathocuproine, and the first doping elements may include cesium (Cs), or other suitable dopants.

In some embodiments, when the second semiconductor device 40 is configured as a 1T FeRAM, where the gate dielectric layer 42 is made of a ferroelectric material such as HZO, the second semiconductor device 40 may further includes a first interface layer 45 formed between the gate dielectric layer 42 and the gate electrode 43, and a second interface layer 46 formed between the gate dielectric layer 42 and the channel 41. Each of the interface layers 45, 46 is made of a high-k dielectric material, and is used for improving the endurance of the 1T FeRAM. In some embodiments, the first interface layer 45 may include titanium oxide, indium oxide, tantalum oxide, or combinations thereof. In some embodiments, the second interface layer 46 may include titanium oxide, indium oxide, or a combination thereof. In some embodiments, each of the interface layers 45, 46 may have a thickness ranging from about 0.5 Å to about 100 nm.

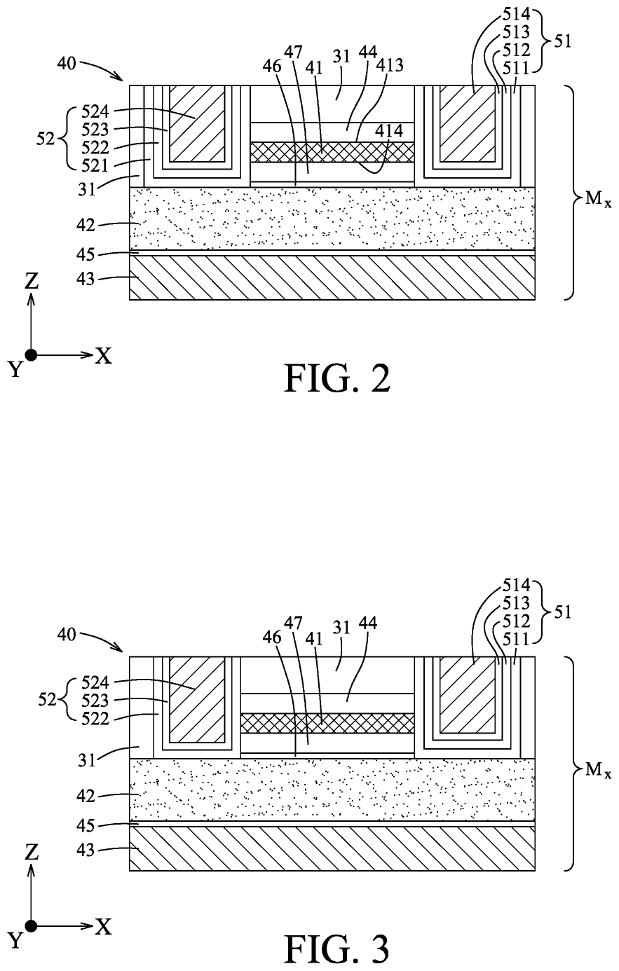

FIG. 2 is a schematic sectional view illustrating the second semiconductor device 40 in accordance with some other embodiments. The second semiconductor device 40 shown in FIG. 2 has a structure similar to the second semiconductor device 40 shown in FIG. 1, but further includes a second confinement layer 47 formed between the channel 41 and the gate dielectric layer 42. In some embodiments, the second confinement layer 47 is formed on the front surface 414 of the channel 41 such that the first and second confinement layers 44, 47 are respectively formed at two opposite sides of the channel 41.

An energy band gap of the second confinement layer 47 is greater than the energy band gap of the channel 41. In some embodiments in which the second semiconductor device 40 is an n-type TFT and the channel 41 is an n-channel, a conduction band edge energy of the second confinement layer 47 is higher than the conduction band edge energy of the channel 41. In some other embodiments in which the second semiconductor device 40 is a p-type TFT and the channel 41 is a p-channel, a valence band edge energy of the second confinement layer 47 is lower than the valence band edge energy of the channel 41. That is, a second carrier barrier height (i.e., the difference in the conduction band edge energy or the difference in the valence band edge energy) is formed at a second heterojunction between the channel 41 and the second confinement layer 47. As shown in FIG. 2, since the channel 41 (which has a relatively narrow energy band gap) is sandwiched between the first confinement layer 44 and the second confinement layer 47 (each having a relatively wide energy band gap), the majority carriers within the channel 41 and confined between the first and second confinement layers 44, 47 may be considered as two-dimensional electron gas flowing in two dimensions, and the mobility of the majority carriers may be significantly enhanced, thereby increasing the on-state drain current (Iₒₙ) of the second semiconductor device 40.

In some embodiments in which the second semiconductor device 40 is an n-type TFT, the second confinement layer 47 includes a second base material selected from gallium oxide, silicon oxide, or aluminum oxide. In some embodiments, the second confinement layer 47 may further include second doping elements so as to adjust the energy band gap of the second confinement layer 47. In some embodiments, the second doping elements doped in the second base material include indium, zinc or a combination thereof. For example, the second confinement layer 47, which may be made of gallium oxide, zinc-doped gallium oxide or indium-doped gallium oxide, may be represented by a chemical formula of (Gaₓ₃R₍₁₋ₓ₃₎)O_{y3}, where R is Zn or In, x3 ranges from about 0.1 to about 1, and y3 ranges from about 0.1 to about 3. As a concentration of the second doping elements in the second confinement layer 47 increases, the energy band gap of the second confinement layer 47 decreases. In some embodiments, the second confinement layer 47 has a first thickness ranging from about 1 Å to about 300 Å. In some embodiments, the energy band gap of the first confinement layer 44 is not less than the energy band gap of the second confinement layer 47. Hence, when the same dopants are applied to the first and second confinement layers 44, 47, a dopant concentration in the first confinement layer 44 is less than a dopant concentration in the second confinement layer 47, and/or the thickness of the first confinement layer 44 is not less than the thickness of the second confinement layer 47. When the energy band gap of the second confinement layer 47 is greater than the energy band gap of the first confinement layer 44 or the thickness of the second confinement layer 47 is greater than the thickness of the first confinement layer 44, an on-state drain current may be undesirably reduced. In some other embodiments in which the second semiconductor device 40 is a p-type TFT, the second confinement layer 47 may be selected from TiSnO₃, Sn₅(PO₅)₂, Ta₂SnO₆, Cs-doped nickel oxide (Cs:NiOₓ), or bathocuproine. In other words, the second base material may be selected from TiSnO₃, Sn₅(PO₅)₂, Ta₂SnO₆, nickel oxide (NiOₓ), or bathocuproine, and the second doping elements may include cesium (Cs), or other suitable dopants.

FIG. 3 is a schematic sectional view illustrating the second semiconductor device 40 in accordance with some yet other embodiments. The second semiconductor device 40 shown in FIG. 3 has a structure similar to the second semiconductor device 40 shown in FIG. 2, but the source-side barrier layer 521 shown in FIG. 2 is omitted. In such case, the channel 41 is instead in contact with the source-side conductive metal oxide layer 522.

The source-side conductive metal oxide layer 522 disposed between the channel 41 and the source-side diffusion blocking layer 523 (or between the channel 41 and the source electrode 524) may prevent formation of an interfacial metal oxide layer, which may be undesirably formed to include metal atoms from the source electrode 524 and oxygen atoms from the channel 41, and which may be, for example, tungsten oxide, titanium oxide, aluminum oxide, and thus have a relatively high electrical resistance. In addition, due to the high donor (i.e., electrons) density of the source-side conductive metal oxide layer 522, the source-side conductive metal oxide layer 522 may be in ohmic contact with the channel 41. Therefore, degradation of an on-state drain current may be prevented or alleviated.

In some alternative embodiments, the semiconductor structure 1 and the second semiconductor device 40 may further include additional features, and/or some features present in the semiconductor structure 1 and the second semiconductor device 40 may be modified, replaced, or eliminated without departure from the spirit and scope of the present disclosure.

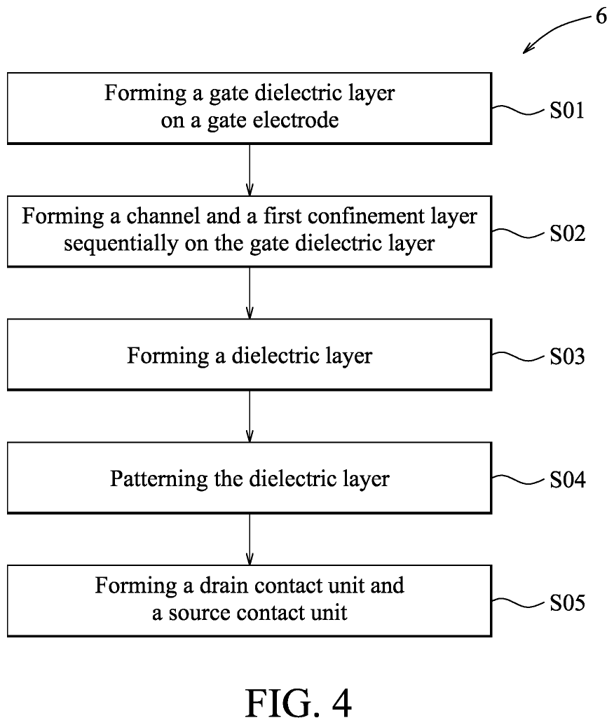

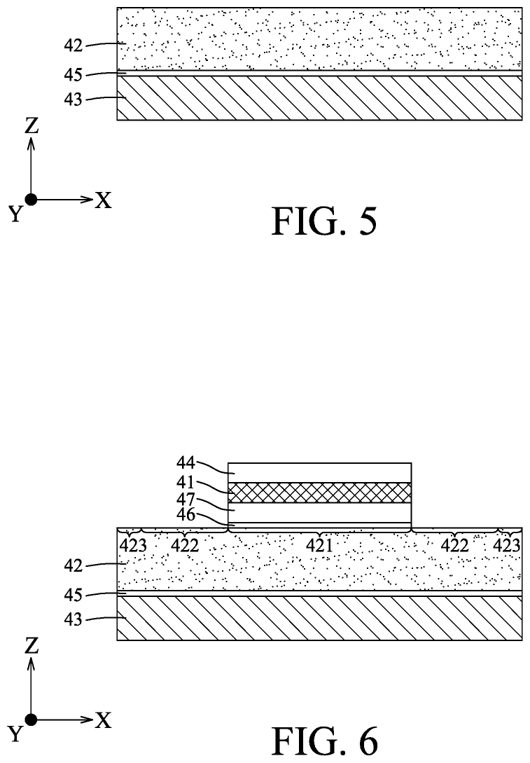

FIG. 4 is a flow diagram illustrating a method 6 for manufacturing the second semiconductor device 40 (e.g., the second semiconductor device 40 shown in FIG. 1, 2 or 3) in accordance with some embodiments. The method 6 may include steps S01 to S05. FIGS. 5 to 11 illustrate schematic views of intermediate stages of the method 6 in accordance with some embodiments. Similar numerals from the above-mentioned embodiments have been used where appropriate, with some construction differences being indicated with different numerals. In some other embodiments, the method 6 may be used for manufacturing a plurality of the second semiconductor devices 40 simultaneously, and the number of the second semiconductor devices 40 may vary according to practical requirements.

Referring to FIG. 4 and the example illustrated in FIG. 5, the method 6 begins at step S01, where the gate dielectric layer 42 is formed on the gate electrode 43 by atomic layer deposition (ALD), physical vapor deposition (PVD), chemical vapor deposition process (CVD), or other suitable deposition techniques. In some embodiments, prior to forming the gate dielectric layer 42, the first interface layer 45 is formed on the gate electrode 43 using ALD, PVD, CVD or other suitable techniques. In some embodiments, a patterning process, which may include a photolithography process and an etching process following the photolithography process, may be performed so that each of the gate electrode 43, the first interface layer 45 and the gate dielectric layer 42 may have a desired dimension in an X direction or in a Y direction that is transverse to the X direction.

Referring to FIG. 4 and the example illustrated in FIG. 6, the method 6 proceeds to step S02, where the channel 41 and the first confinement layer 44 are sequentially formed on the first region 421 of the gate dielectric layer 42 by a suitable deposition process (such as the examples described in step S01) and a patterning process which may include a photolithography process and an etching process following the photolithography process. In some embodiments, prior to forming the channel 41, the second interface layer 46 is formed on the first region 421 of the gate dielectric layer 42 by the above-mentioned processes. FIG. 6 is a schematic sectional view similar to that shown in FIG. 5, but illustrating the structure after step S02.

In some embodiments, as shown in FIG. 6, in the process for forming the second semiconductor device 40 shown in FIG. 2 or 3, step S02 may include forming the second interface layer 46, the second confinement layer 47, the channel 41 and the first confinement layer 44 sequentially on the first region 421 of the gate dielectric layer 42 by the above-mentioned processes. In some other embodiments, in the process for forming the second semiconductor device 40 shown in FIG. 1, formation of the second confinement layer 47 may be omitted. That is, step S02 may include forming the second interface layer 46, the channel 41 and the first confinement layer 44 sequentially on the first region 421 of the gate dielectric layer 42 by the above-mentioned processes.

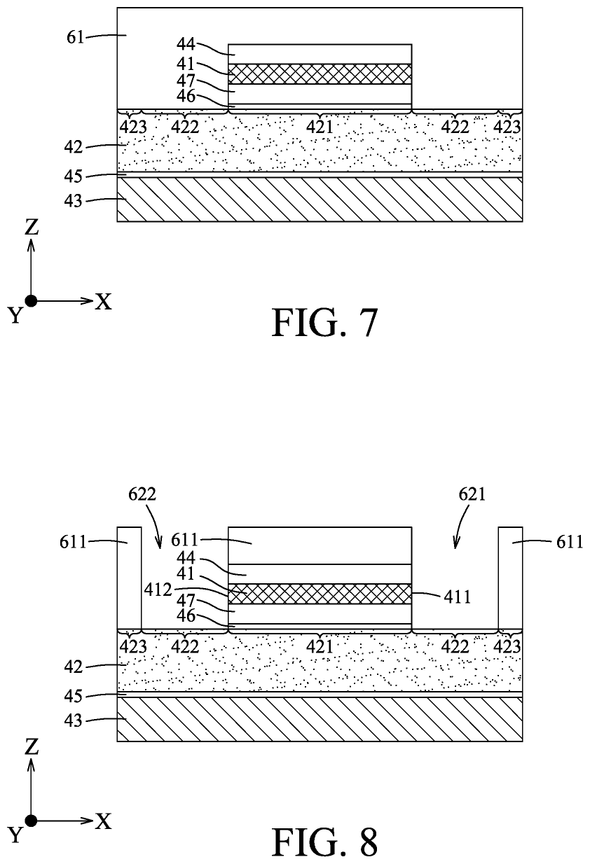

Referring to FIG. 4 and the example illustrated in FIG. 7, the method 6 proceeds to step S03, where a dielectric layer 61 for forming the IMD portion 31 of the interconnect layer Mₓ (see FIG. 1, 2 or 3) is formed on the structure obtained after step S02 using a suitable deposition process (such as the examples described in step S01), followed by a planarization process, such as chemical mechanical polishing, to obtain a planar upper surface of the dielectric layer 61. FIG. 7 is a schematic sectional view similar to that shown in FIG. 6, but illustrating the structure after step S03.

As shown in FIG. 7, in some embodiments, the dielectric layer 61 is formed on a stack of the second interface layer 46, the second confinement layer 47, the channel 41 and the first confinement layer 44, and extends to cover the second and third regions 422, 423 of the gate dielectric layer 42 opposite to the gate electrode 43.

Referring to FIG. 4 and the example illustrated in FIG. 8, the method 6 proceeds to step S04, where the dielectric layer 61 (see FIG. 7) is patterned to have two openings 621, 622 spaced apart from each other. Step S04 is performed by, for example, a photolithography process and an etching process following the photolithography process. In addition, the two second regions 422 of the gate dielectric layer 42 are respectively exposed from the two openings 621, 622. The two openings 621, 622 are respectively for forming the drain and source contact units 51, 52 (see FIG. 1, 2 or 3) therein. FIG. 8 is a schematic sectional view similar to that shown in FIG. 7, but illustrating the structure after step S04.

In some embodiments, as shown in FIG. 8, two opposite side surfaces of each of the second interface layer 46, the second confinement layer 47, the channel 41 and the first confinement layer 44 are respectively exposed from the two openings 621, 622. That is, the drain-side surface 411 and the source-side surface 412 of the channel 41 are respectively exposed from the two openings 621, 622. After step S04, the patterned dielectric layer is denoted by the numeral 611.

Referring to FIG. 4 and the example illustrated in FIGS. 2, 3, 9 to 11, the method 6 proceeds to step S05, where the drain contact unit 51 is formed in the opening 621 (see FIG. 8) and the source contact unit 52 is formed in the opening 622, thereby obtaining the semiconductor device 40 shown in FIG. 1, 2 or 3. In some embodiments in which the drain and source contact units 51, 52 have the same film stacking, as shown in FIG. 1 or 2, the drain and source contact units 51, 52 may be formed at the same time, while in some other embodiments in which the drain and source contact units 51, 52 have different film stacking, as shown in FIG. 3, the drain and source contact units 51, 52 may be separately formed.

Specifically, in some embodiments, in the process for forming the drain and source contact units 51, 52 shown in FIG. 1 or 2, step S05 may include sequentially depositing materials respectively for forming the drain-side and source-side barrier layers 511, 521, the drain-side and source-side conductive metal oxide layers 512, 522, the drain-side and source-side diffusion blocking layers 513, 523, and the drain and source electrodes 514, 524 along an inner surface of each of the openings 621, 622 over the patterned dielectric layer 611 to fill the openings 621, 622 (see FIG. 8) by suitable deposition processes, followed by performing a planarization process, such as chemical mechanical polishing, for a period of time until the patterned dielectric layer 611 is exposed. Thereafter, the patterned dielectric layer 611 is formed into the IMD portion 31 of the interconnect layer Mₓ.

In some other embodiments, in the process for forming the drain and source contact units 51, 52 shown in FIG. 3, step S05 may include sub-steps shown in FIGS. 9 to 11 and 3.

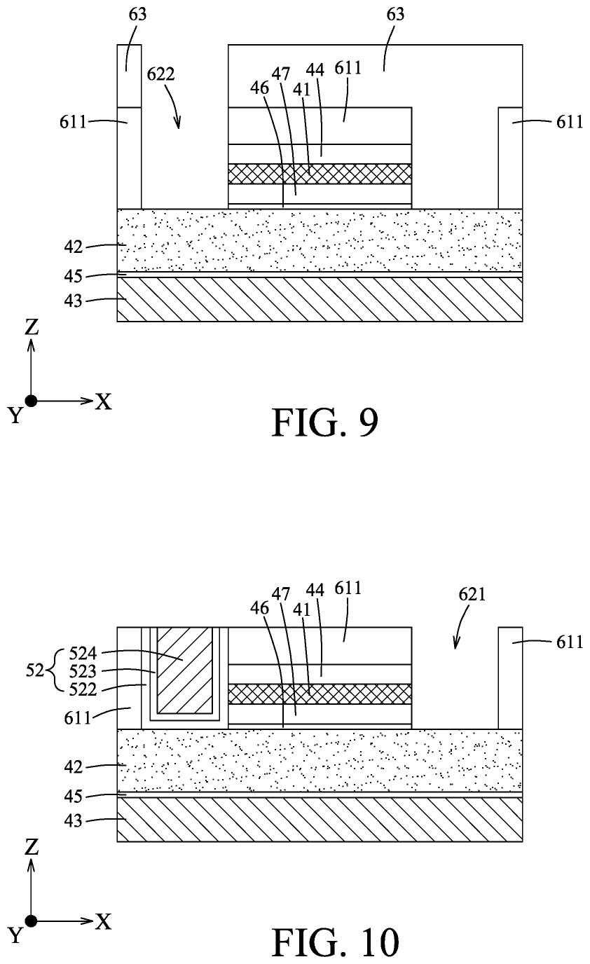

In the sub-step shown in FIG. 9, a first masking layer 63 is partially formed on the structure obtained after step S04 such that the opening 621 (see FIG. 8) is covered by the first masking layer 63 and the opening 622 is exposed from the first masking layer 63. In some embodiments, the first masking layer 63 may include an oxide, a nitride, a carbide, an oxynitride, an oxycarbide, a carbonitride, an oxycarbonitride, or combinations thereof. For example, the first masking layer 63 may be made of silicon oxide, aluminum oxide, hafnium oxide, zirconium oxide, silicon nitride, aluminum nitride, titanium nitride, silicon carbide, silicon oxycarbide, silicon oxynitride, silicon carbonitride, silicon oxycarbonitride, or combinations thereof. Other materials suitable for forming the first masking layer 63 are within the contemplated scope of the present disclosure.

In the sub-step shown in FIG. 10, the source contact unit 52 (see also FIG. 3) is formed after the first masking layer 63 is formed. In some embodiments, formation of the source contact unit 52 may include sequentially depositing materials respectively for forming the source-side conductive metal oxide layer 522, the source-side diffusion blocking layer 523 and the source electrode 524 along the inner surface of the opening 622 (see FIG. 9) to fill the opening 622 (see FIG. 9) by suitable deposition processes; performing a planarization process, such as chemical mechanical polishing, for a period of time until the patterned dielectric layer 611 is exposed; and performing an etching process (e.g., a dry etching and/or a wet etching) to remove the first masking layer 63 (see FIG. 9).

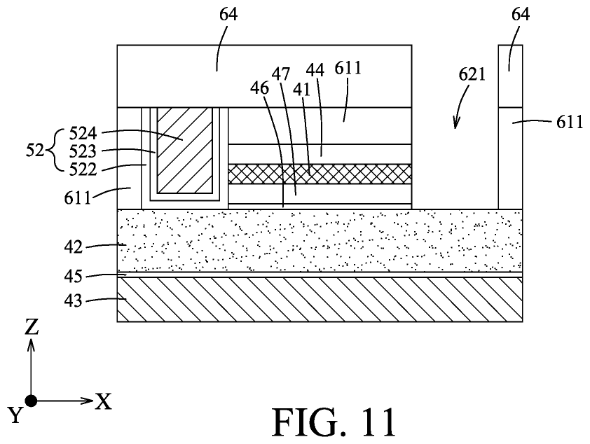

In the sub-step shown in FIG. 11, after forming the source contact unit 52, a second masking layer 64 is partially formed on the structure shown in FIG. 10 such that the source contact unit 52 is covered by the second masking layer 64 and the opening 621 is exposed from the second masking layer 64. In some embodiments, possible materials suitable for forming the second masking layer 64 are similar to those for forming the first masking layer 63, and thus the details thereof are omitted for the sake of brevity. Other materials suitable for forming the second masking layer 64 are within the contemplated scope of the present disclosure.

In the sub-step shown in FIG. 3, the drain contact unit 51 (see also FIG. 3) is formed after the second masking layer 64 is formed. In some embodiments, formation of the drain contact unit 51 may include sequentially depositing materials respectively for forming the drain-side barrier layer 511, the drain-side conductive metal oxide layer 512, the drain-side diffusion blocking layer 513 and the drain electrode 514 along the inner surface of the opening 621 (see FIG. 11) to fill the opening 621 (see FIG. 11) by suitable deposition processes, followed by performing a planarization process, such as chemical mechanical polishing, for a period of time until the patterned dielectric layer 611 is exposed. After the planarization process, the patterned dielectric layer 611 is formed into the IMD portion 31 of the interconnect layer Mₓ. In some embodiments exemplified by FIGS. 3 and 9 to 11, the drain contact unit 51 is formed after formation of the source contact unit 52; while in some other embodiments, the drain contact unit 51 is formed before formation of the source contact unit 52.

In some embodiments, some steps in the method 6 may be modified, replaced, or eliminated without departure from the spirit and scope of the present disclosure.

In summary, by selecting the materials of the drain-side and source-side barrier layers 511, 521, the threshold voltage (e.g., Vₜ, or Vₜ₍ᵢₙᵢₜᵢₐₗ₎, V_{t(PRG)}, V_{t(ERS)}, etc.) of the n-type TFT 40 may be shifted to a relatively positive value (e.g., shifted from about −0.02 V to about 0.26 V, or shifted from about −1 V to about 2 V), and the threshold voltage of the p-type TFT 40 may be shifted to a relatively negative value. Accordingly, current leakage may be suppressed and degradation of an on-state drain current (Iₒₙ) may be alleviated. Furthermore, with the provision of the first and second confinement layers 44, 47 which are respectively located at two opposite sides of the channel 41 and which have a relatively wide energy band gap than that of the channel 41, the mobility of the majority carriers within the channel 41 may be increased, thereby increasing the on-state drain current (Iₒₙ) of the semiconductor device 40. In addition, since the energy band gap of the first confinement layer 44 is relatively wide, the back-channel current leakage in the semiconductor device 40 may be further reduced.

In accordance with some embodiments of the present disclosure, a method for manufacturing a semiconductor structure includes: forming a gate electrode; forming a gate dielectric layer over the gate electrode; forming a channel over the gate dielectric layer opposite to the gate electrode, the channel including a semiconductor material; forming a first confinement layer on the channel opposite to the gate electrode, an energy band gap of the first confinement layer being greater than an energy band gap of the channel; and forming a drain electrode and a source electrode which are connected to the channel, the drain electrode and the source electrode being spaced apart from each other and each including an electrically conductive material.

In accordance with some embodiments of the present disclosure, the semiconductor material has an n-type conductivity, and a conduction band edge energy of the first confinement layer is higher than a conduction band edge energy of the channel.

In accordance with some embodiments of the present disclosure, the semiconductor material has a p-type conductivity, and a valence band edge energy of the first confinement layer is lower than a valence band edge energy of the channel.

In accordance with some embodiments of the present disclosure, the method further includes forming a second confinement layer between the channel and the gate dielectric layer. An energy band gap of the second confinement layer is greater than the energy band gap of the channel.

In accordance with some embodiments of the present disclosure, the energy band gap of the first confinement layer is not less than the energy band gap of the second confinement layer.

In accordance with some embodiments of the present disclosure, a thickness of the first confinement layer is not less than a thickness of the second confinement layer.

In accordance with some embodiments of the present disclosure, the first confinement layer includes a first base material selected from gallium oxide, silicon oxide, aluminum oxide, TiSnO₃, Sn₅(PO₅)₂, Ta₂SnO₆, nickel oxide, or bathocuproine, and the second confinement layer includes a second base material selected from gallium oxide, silicon oxide, aluminum oxide, TiSnO₃, Sn₅(PO₅)₂, Ta₂SnO₆, nickel oxide, or bathocuproine.

In accordance with some embodiments of the present disclosure, the first confinement layer further includes first doping elements, and the second confinement layer further includes second doping elements.

In accordance with some embodiments of the present disclosure, the first doping elements include indium, zinc, cesium, or combinations thereof, and the second doping elements includes indium, zinc, cesium, or combinations thereof.

In accordance with some embodiments of the present disclosure, a method for manufacturing a semiconductor structure includes: forming a gate electrode; forming a gate dielectric layer over the gate electrode; forming a channel over the gate dielectric layer opposite to the gate electrode, the channel including a semiconductor material; forming a confinement layer on the channel opposite to the gate electrode, an energy band gap of the confinement layer being greater than an energy band gap of the channel; forming a drain-side barrier layer in contact with the channel so as to form a first barrier height at an interface between the drain-side barrier layer and the channel, an energy band gap of the drain-side barrier layer being greater than the energy band gap of the channel; and forming a drain electrode and a source electrode, the drain electrode being connected to the channel through the drain-side barrier layer, the source electrode being connected to the channel, the drain electrode and the source electrode being spaced apart from each other and each including an electrically conductive material.

In accordance with some embodiments of the present disclosure, the method further includes forming a source-side barrier layer between the source electrode and the channel so as to form a second barrier height at an interface between the source-side barrier layer and the channel. An energy band gap of the source-side barrier layer is greater than the energy band gap of the channel.

In accordance with some embodiments of the present disclosure, the first barrier height is greater than the second barrier height.

In accordance with some embodiments of the present disclosure, a thickness of the drain-side barrier layer is not less than a thickness of the source-side barrier layer.

In accordance with some embodiments of the present disclosure, the drain-side barrier layer includes a drain barrier material selected from gallium oxide, silicon oxide, aluminum oxide, TiSnO₃, Sn₅(PO₅)₂, Ta₂SnO₆, nickel oxide, or bathocuproine, and the source-side barrier layer includes a source barrier material selected from gallium oxide, silicon oxide, aluminum oxide, TiSnO₃, Sn₅(PO₅)₂, Ta₂SnO₆, nickel oxide, or bathocuproine.

In accordance with some embodiments of the present disclosure, the drain-side barrier layer further includes first dopants selected from indium, zinc, cesium, or combinations thereof, the source-side barrier layer further includes second dopants selected from indium, zinc, cesium, or combinations thereof, and the energy band gap of the drain-side barrier layer is greater than the energy band gap of the source-side barrier layer.

In accordance with some embodiments of the present disclosure, the method further includes: forming a drain-side conductive metal oxide layer between the drain electrode and the drain-side barrier layer; and forming a source-side conductive metal oxide layer which is disposed between the source electrode and the channel and which is in ohmic contact with the channel.

In accordance with some embodiments of the present disclosure, the drain-side conductive metal oxide layer includes indium gallium zinc oxide, indium gallium oxide, indium zinc oxide, indium oxide, zinc oxide, zinc tin oxide, gallium zinc oxide, indium tin oxide, fluorine-doped tin oxide, or combinations thereof, and the source-side conductive metal oxide layer includes indium gallium zinc oxide, indium gallium oxide, indium zinc oxide, indium oxide, zinc oxide, zinc tin oxide, gallium zinc oxide, indium tin oxide, fluorine-doped tin oxide, or combinations thereof.

In accordance with some embodiments of the present disclosure, a semiconductor structure includes: a gate electrode; a gate dielectric layer disposed over gate electrode, the gate dielectric layer including a ferroelectric material; a channel disposed over the gate dielectric layer, the channel including a semiconductor material; a drain contact unit and a source contact unit connected to the channel and spaced apart from each other; and a first confinement layer disposed on the channel opposite to the gate electrode, an energy band gap of the first confinement layer being greater than an energy band gap of the channel.

In accordance with some embodiments of the present disclosure, the semiconductor structure further includes a second confinement layer disposed between the channel and the gate dielectric layer. An energy band gap of the second confinement layer is greater than the energy band gap of the channel.

In accordance with some embodiments of the present disclosure, the drain contact unit includes: a drain-side barrier layer disposed on the channel, an energy band gap of the drain-side barrier layer being greater than the energy band gap of the channel; a drain-side conductive metal oxide layer disposed on the drain-side barrier layer opposite to the channel; and a drain electrode disposed on the drain-side conductive metal oxide layer opposite to the drain-side barrier layer, the drain electrode including a first electrically conductive material. The source contact unit includes a source electrode which includes a second electrically conductive material, and a source-side conductive metal oxide layer which is disposed between the source electrode and the channel and which is in ohmic contact with the channel.

In accordance with some embodiments of the present disclosure, a method for manufacturing a semiconductor structure includes: forming a gate electrode; forming a gate dielectric layer over gate electrode, the gate dielectric layer including a ferroelectric material; forming a channel over the gate dielectric layer, the channel including a semiconductor material; forming a confinement layer over the channel opposite to the gate electrode, an energy band gap of the confinement layer being greater than an energy band gap of the channel; and forming a drain contact unit connected to the channel; and forming a source contact unit connected to the channel, the source contact unit being spaced apart from the drain contact unit.

In accordance with some embodiments of the present disclosure, the drain contact unit and the source contact unit are separately formed.

In accordance with some embodiments of the present disclosure, formation of the drain contact unit includes forming a drain-side barrier layer on the channel, forming a drain-side conductive metal oxide layer on the drain-side barrier layer opposite to the channel, and forming a drain electrode on the drain-side conductive metal oxide layer opposite to the drain-side barrier layer. Formation of the source contact unit includes forming a source-side conductive metal oxide layer on and in ohmic contact with the channel, and forming a source electrode on the source-side conductive metal oxide layer opposite to the channel. An energy band gap of the drain-side barrier layer is greater than the energy band gap of the channel. Each of the drain electrode and the source electrode includes an electrically conductive material.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a gate electrode;
forming a gate dielectric layer over the gate electrode;
forming a channel over the gate dielectric layer opposite to the gate electrode, the channel including a semiconductor material;
forming a first confinement layer on the channel opposite to the gate electrode, an energy band gap of the first confinement layer being greater than an energy band gap of the channel; and
forming a drain electrode and a source electrode which are connected to the channel, the drain electrode and the source electrode being spaced apart from each other and each including an electrically conductive material.

2. The method as claimed in claim 1, wherein
the semiconductor material has an n-type conductivity, and
a conduction band edge energy of the first confinement layer is higher than a conduction band edge energy of the channel.

3. The method as claimed in claim 1, wherein
the semiconductor material has a p-type conductivity, and
a valence band edge energy of the first confinement layer is lower than a valence band edge energy of the channel.

4. The method as claimed in claim 1, further comprising forming a second confinement layer between the channel and the gate dielectric layer, an energy band gap of the second confinement layer being greater than the energy band gap of the channel.

5. The method as claimed in claim 4, wherein the energy band gap of the first confinement layer is not less than the energy band gap of the second confinement layer.

6. The method as claimed in claim 4, wherein a thickness of the first confinement layer is not less than a thickness of the second confinement layer.

7. The method as claimed in claim 4, wherein
the first confinement layer includes a first base material selected from gallium oxide, silicon oxide, aluminum oxide, TiSnO₃, Sn₅(PO₅)₂, Ta₂SnO₆, nickel oxide, or bathocuproine, and
the second confinement layer includes a second base material selected from gallium oxide, silicon oxide, aluminum oxide, TiSnO₃, Sn₅(PO₅)₂, Ta₂SnO₆, nickel oxide, or bathocuproine.

8. The method as claimed in claim 7, wherein the first confinement layer further includes first doping elements, and the second confinement layer further includes second doping elements.

9. The method as claimed in claim 8, wherein
the first doping elements include indium, zinc, cesium, or combinations thereof, and
the second doping elements includes indium, zinc, cesium, or combinations thereof.

10. A method for manufacturing a semiconductor structure, comprising:
forming a gate electrode;
forming a gate dielectric layer over the gate electrode;
forming a channel over the gate dielectric layer opposite to the gate electrode, the channel including a semiconductor material;
forming a confinement layer on the channel opposite to the gate electrode, an energy band gap of the confinement layer being greater than an energy band gap of the channel;
forming a drain-side barrier layer in contact with the channel so as to form a first barrier height at an interface between the drain-side barrier layer and the channel, an energy band gap of the drain-side barrier layer being greater than the energy band gap of the channel; and
forming a drain electrode and a source electrode, the drain electrode being connected to the channel through the drain-side barrier layer, the source electrode being connected to the channel, the drain electrode and the source electrode being spaced apart from each other and each including an electrically conductive material.

11. The method as claimed in claim 10, further comprising forming a source-side barrier layer between the source electrode and the channel so as to form a second barrier height at an interface between the source-side barrier layer and the channel, an energy band gap of the source-side barrier layer being greater than the energy band gap of the channel.

12. The method as claimed in claim 11, wherein the first barrier height is greater than the second barrier height.

13. The method as claimed in claim 11, wherein a thickness of the drain-side barrier layer is not less than a thickness of the source-side barrier layer.

14. The method as claimed in claim 11, wherein
the drain-side barrier layer includes a drain barrier material selected from gallium oxide, silicon oxide, aluminum oxide, TiSnO₃, Sn₅(PO₅)₂, Ta₂SnO₆, nickel oxide, or bathocuproine, and
the source-side barrier layer includes a source barrier material selected from gallium oxide, silicon oxide, aluminum oxide, TiSnO₃, Sn₅(PO₅)₂, Ta₂SnO₆, nickel oxide, or bathocuproine.

15. The method as claimed in claim 14, wherein
the drain-side barrier layer further includes first dopants selected from indium, zinc, cesium, or combinations thereof,
the source-side barrier layer further includes second dopants selected from indium, zinc, cesium, or combinations thereof, and
the energy band gap of the drain-side barrier layer is greater than the energy band gap of the source-side barrier layer.

16. The method as claimed in claim 10, further comprising:
forming a drain-side conductive metal oxide layer between the drain electrode and the drain-side barrier layer; and
forming a source-side conductive metal oxide layer which is disposed between the source electrode and the channel and which is in ohmic contact with the channel.

17. The method as claimed in claim 16, wherein
the drain-side conductive metal oxide layer includes indium gallium zinc oxide, indium gallium oxide, indium zinc oxide, indium oxide, zinc oxide, zinc tin oxide, gallium zinc oxide, indium tin oxide, fluorine-doped tin oxide, or combinations thereof, and
the source-side conductive metal oxide layer includes indium gallium zinc oxide, indium gallium oxide, indium zinc oxide, indium oxide, zinc oxide, zinc tin oxide, gallium zinc oxide, indium tin oxide, fluorine-doped tin oxide, or combinations thereof.

18. A semiconductor structure, comprising:
a gate electrode;
a gate dielectric layer disposed over gate electrode, the gate dielectric layer including a ferroelectric material;
a channel disposed over the gate dielectric layer, the channel including a semiconductor material;
a drain contact unit and a source contact unit connected to the channel and spaced apart from each other; and
a first confinement layer disposed on the channel opposite to the gate electrode, an energy band gap of the first confinement layer being greater than an energy band gap of the channel.

19. The semiconductor structure as claimed in claim 18, further comprising a second confinement layer disposed between the channel and the gate dielectric layer, an energy band gap of the second confinement layer being greater than the energy band gap of the channel.

20. The semiconductor structure as claimed in claim 18, wherein
the drain contact unit includes
a drain-side barrier layer disposed on the channel, an energy band gap of the drain-side barrier layer being greater than the energy band gap of the channel,
a drain-side conductive metal oxide layer disposed on the drain-side barrier layer opposite to the channel, and
a drain electrode disposed on the drain-side conductive metal oxide layer opposite to the drain-side barrier layer, the drain electrode including a first electrically conductive material, and
the source contact unit includes
a source electrode which includes a second electrically conductive material, and
a source-side conductive metal oxide layer which is disposed between the source electrode and the channel and which is in ohmic contact with the channel.
